(19) United States
(12) Patent Application Publication
(10) Pub. No.: US 2004/0243917 A1
(43) Pub. Date: Dec. 2, 2004

(54) Apparatus and method for decoding a low density parity check code in a communication system

(75) Inventors: Seung-Bum Suh, Seoul (KR); Hong-Yeop Song, Seoul (KR); Min-Ho Shin, Seoul (KR); Joon-Sung Kim, Seoul (KR)

Correspondence Address: DILWORTH & BARRESE, LLP, 333 EARLE OVINGTON BLVD., UNIONDALE, NY, 11553, US

(73) Assignees: SAMSUNG ELECTRONICS CO., LTD., GYEONGGI-DO (KR); YONSEI UNIVERSITY, SEOUL (KR)

(21) Appl. No.: 10/854,597

(22) Filed: May 26, 2004

(30) Foreign Application Priority Data
May 26, 2003 (KR) 2003-33456

(51) Int. Cl. H03M 13/00; G06F 11/00

(52) U.S. Cl. 714/801

(57) ABSTRACT

An apparatus and method for improving decoding performance of a Normalized-BP algorithm in an LDPC-code decoder. The present invention to provides an LDPC-code decoding apparatus, which can be implemented in the form of a simpler configuration than the LLR-BP algorithm, and a method for controlling the same. Further, the present invention provides an LDPC-code decoding apparatus, which improves decoding performance of the Normalized-BP algorithm and at the same time provides similar performance to that of the LLR-BP algorithm, and a method for controlling the same.

### PRIORITY

This application claims priority to an application entitled “APPARATUS AND METHOD FOR DECODING LDPC (LOW DENSITY PARITY CHECK CODE) IN COMMUNICATION SYSTEM”, filed in the Korean Intellectual Property Office on May 26, 2003 and assigned Serial No. 2003-33456, the contents of which are hereby incorporated by reference.

### BACKGROUND OF THE INVENTION

1. Field of the Invention

The present invention relates generally to a Forward Error Correction (FEC) apparatus and method for use in a digital communication system, and more particularly to an apparatus and method for decoding an FEC code in a digital communication system for transmitting high-speed data.

2. Description of the Related Art

Conventionally, digital communication systems generate many errors due to noise generated from a transmission path. Accordingly, over the years, a variety of solutions have been presented to correct or eliminate these errors. A wireless communication system based on the 3GPP or 3GPP2 specification proposed using convolutional codes to transmit voice and control signals, and also proposed using turbo codes to effectively transmit high-speed data. The turbo code for high-speed data transmission has an advantage in that it has an extremely low BER (Bit Error Rate) at a low SNR (Signal to Noise Ratio), but it has a number of disadvantages in its performance and implementation.

Firstly, the turbo code has a relatively short minimum distance of a codeword. Therefore, when decoding a signal coded with the turbo code, there may arise an error floor at a desired BER location. The turbo code has another disadvantage in that it has a relatively high undetected error probability in association with a codeword for generating errors in a decoding mode.

Secondly, a decoding process of the turbo code requires an effective decoding stop function to reduce not a decoding time and its power consumption, such that it requires either a CRC (Cyclic Redundancy Check) process to detect errors for every iterative decoding process, or an additional algorithm to perform a decoding stop process, resulting in implementation of an effective decoding stop function.

Thirdly, an algorithm for decoding the turbo code cannot be implemented in the form of a parallel architecture, resulting in limitation in improving a decoding speed.

Therefore, recently, an LDPC (Low Density Parity Check) code, which has excellent performance and functions as a new code capable of solving the aforementioned problems, has been developed. The LDPC code contains a very small number of a specific number “1” in individual rows and columns of a parity check matrix for code definition, and its architecture can be defined by a factor graph comprising a check node, a variable node, and an edge for interconnecting the check node and the variable node. The LDPC code has a longer minimum distance as compared to the turbo code, such that an error floor occurs at a very lower BER as compared to the turbo code and undetected error probability for an erroneous codeword is a very low value experimentally approximating zero. Additionally, the LDPC code can be implemented in the form of a parallel architecture, resulting in a reduced decoding time. The LDPC code can perform an effective decoding stop function without using either an overhead, such as a CRC, or a specific decoding stop algorithm having been added through the use of a parity check process performed for each iterative decoding process.

The LDPC code is a linear block code in which most elements of a parity check matrix H are each equal to ‘0’, and uses a probable iterative decoding method using a simple parity check equation, resulting in improvement of performance. The decoding method for the LDPC is designed to search for the most probable codeword by which the multiplication of a reception signal vector and a parity check matrix satisfies a specific value of ‘0’.

A Sum-Product algorithm acting a representative LDPC-code decoding method performs a soft-decision iterative decoding process using a probability value to search for the above codeword. More specifically, the Sum-Product algorithm updates a probability value of each bit using a reception vector and a channel characteristic for every iterative decoding process, such that it can search for a codeword having the multiplied result ‘0’ associated with the parity check matrix.

Another LDPC-code decoding method is an LLR-Belief Propagation (LLR-BP) algorithm for calculating a message propagated using an LLR (Log-Likelihood Ratio). Except for one characteristic in which the LLR value is used instead of a real probability value during the calculation time of the propagation message, the LLR-BP algorithm can be considered to be the same algorithm as the Sum-Product algorithm. The LLR-BP algorithm has excellent performance because it approximates Shannon's theoretical channel capacitance boundary on the assumption that the length of a codeword is sufficiently long. However, the LLR-BP algorithm uses a log function and a hyper-tangent (tan h) function for use in the iterative decoding process, thereby increasing calculation complexity and difficulty in its real implementation.

Accordingly, improved algorithms have been proposed by Chen and Fossorier et al., who have published a research paper entitled “REDUCED COMPLEXITY ITERATIVE DECODING OF LOW DENSITY PARITY CHECK CODES BASED ON BELIEF PROPAGATION” in the IEEE trans. Commun., vol. 47, pp. 673˜680 on May 1999.

The above algorithms are a UMP-BP (Uniformly Most Powerful-Belief Propagation) algorithm and a Normalized-BP (Normalized-Belief Propagation) algorithm, which reduce iterative decoding complexity and encounter less performance deterioration as compared to the conventional LLR-BP algorithm. The UMP-BP algorithm prevents a log function and a tan h function from being used in a row-directional iterative decoding process of the LLR-BP algorithm, selects a bit value having the lowest LLR from among a plurality of bits associated with a given parity check equation, and approximates the selected bit value, considerably reduced complexity. The Normalized-BP algorithm approximates the row-directional iterative decoding process in the same manner as in the UMP-BP algorithm, largely reducing calculation complexity. The UMP-BP method has introduced a standardized factor concept, such that it prevents a message value from being higher than that of the LLR-BP algorithm due to the LLR omission in such approximation. Therefore, the UMP-BP algorithm can implement performance similar to that of the LLR-BP algorithm. The UMP-BP algorithm utilizes a specific omission part to reduce complexity, such that its bit-average LLR is higher than that of the LLR-BP algorithm. Therefore, the Normalized-BP algorithm utilizes a normalization factor alpha scheme to reduce the difference between the above two LLRs, such that it allows an average value of individual LLRs to be similar to that of the LLR-BP algorithm, resulting in performance, which is superior to that of the UMP-BP algorithm.

FIG. 1 is a conceptual diagram illustrating a relationship between check nodes and variable nodes to explain a factor process for decoding the LDPC code. Referring to FIG. 1, symbols coded by the LDPC code matrix are transmitted via wireless channel environments, and individual coded symbols enter bit nodes ( . . . , 111, 112, 113, 114, . . . ). The bit nodes ( . . . , 111, 112, 113, 114, . . . ) receive LLR values of entry coded symbols, and transmit the received LLR values to individual check nodes ( . . . , 121, 122, 123, 124, 125, . . . ). Individual check nodes ( . . . , 121, 122, 123, 124, 125, . . . ) perform their operations using different using the aforementioned methods, and transmit the operation results to the bit nodes ( . . . , 111, 112, 113, 114, . . . ). It is determined whether the values transmitted to the bit nodes ( . . . , 111, 112, 113, 114, . . . ) satisfy parity check requirements in a temporary decoding process. If it is determined that the parity check requirements have been satisfied, a decoding process for corresponding symbols is terminated. However, if it is determined that the parity check requirements have not been satisfied, values to be detected are re-calculated using a transmission/operation method between bit nodes ( . . . , 111, 112, 113, 114, . . . ) and check nodes ( . . . , 121, 122, 123, 124, 125, . . . ).

FIG. 2 is a flow chart illustrating the Normalized-BP algorithm. Referring to FIG. 2, upon receiving coded symbols from a wireless channel, the LDPC decoder performs an initialization process at step 200. The initialization process determines values Zₘₙ of bit nodes, and determines the values Zₘₙ to be values of individual initial-entry coded symbols yₙ. The values Zₘₙ of the bit nodes identify an LLR ranging from a bit node N to a check node m. After finishing the initial value setup process, individual bit nodes ( . . . , 111, 112, 113, 115, . . . ) of the LDPC decoder perform operations for bits to be calculated in a row-directional iterative decoding process at step 202. Such operation determines an initial-entry value as shown in Equation 1, and operates a modulo-2-sum operation of the remaining bits using all parity check equations associated with bits to be calculated on the basis of the determined values.

$$\begin{matrix}{σ}_{mn} = \{ \begin{matrix}1 , & if {z}_{mn} > 0 \\ 0 , & if {z}_{mn} \leq 0\end{matrix} , & {σ}_{m} = {\sum }_{n ∈ N ( m )} {σ}_{mn} mod 2\end{matrix} \qquad [ Equation 1 ]$$

Referring to Equation 1, σₘₙ is represents values received from a bit node ‘m’ to an n-th check node, and σₘ is a value determined by an m-th bit node.

After performing the aforementioned calculation, individual bit nodes ( . . . , 111, 112, 113, 115, . . . ) select their codes using the calculated value so as to enable a parity check equation to satisfy the value ‘0’. Thereafter, the LDPC decoder calculates LLR values of individual selection codes of the bit nodes ( . . . , 111, 112, 113, 115, . . . ) using Equation 2 at step 204. Equation 2 corrects a mean message value using the aforementioned standardized factor.

$${L}_{mn} = {( - 1 )}^{\overline{{σ}_{m} ⊕ {σ}_{mn}}} {min}_{{n}^{′} ∈ N ( m ) \backslash n} \vert {z}_{{mn}^{′}} \vert / α \qquad [ Equation 2 ]$$

The row-directional iterative decoding process shown in Equation 2 integrates an initially-received value and calculation values of individual parity check equations as one value, such that it determines a bit code to be calculated. Equation 2 represents a row-directional iterative decoding process for the Normalized-BP algorithm, where Zₘₙ is an LLR of the bit ‘n’ propagated from the bit ‘n’ to a parity check equation ‘m’, and a is a standardized factor for use in the Normalized-BP algorithm. During the initial driving time of the Normalized-BP algorithm, LLR values of individual bits are initialized to a reception value. If codes of all bits have been determined using the aforementioned process, the LDPC decoder performs a column-directional iterative decoding process at step 206. In this case, the column-directional iterative decoding process is a process for updating the value of Zₘₙ, and it can be represented by Equation 3.

$${Z}_{mn} = {y}_{n} + {\sum }_{{m}^{′} ∈ M ( n ) \backslash m} {L}_{{m}^{′} n} \qquad [ Equation 3 ]$$

If the column-directional iterative decoding process can be carried out using Equation 3, the LDPC decoder determines whether the number of iterative decoding times is equal to a prescribed maximum number of iterative decoding times at step 208. The maximum number of iterative decoding times is used to halt the decoding operation on the condition that very-low decoding success probability is provided when continuously performing an iterative decoding operation. If the LDPC decoder has performed the decoding operation the maximum decoding times at step 208, it performs a decoding failure process at step 212. However, if the LDPC decoder not has performed the decoding operation the maximum decoding times, it performs a temporary decoding process at step 210. The temporary decoding process can be performed using Equation 4:

$${Z}_{n} = {y}_{n} + {\sum }_{m ∈ M ( n )} {L}_{mn} , \{ \begin{matrix}\hat{c} = 1 & if {Z}_{n} > 0 \\ \hat{c} = 0 & if {Z}_{n} < 0\end{matrix} \qquad [ Equation 4 ]$$

The value of Zₙ can be calculated using Equation 4, such that values of c of code symbols are determined, the LDPC decoder performs a parity check such that it determines whether a parity check result is satisfied or not at step 214. The parity check is identifies a matrix in which the reception coded symbols must satisfy a predetermined condition of Equation 5, such that its result can be recognized by determining whether the coded symbols satisfy the predetermined condition of Equation 5:

Hĉ=0 [Equation 5]

If the parity check result of Equation 5 identifies a good state, i.e., in the case of passing the parity check process, the LDPC decoder terminates the decoding process for corresponding symbols at step 216. However, when the parity check process is not satisfied, the LDPC decoder returns to step 202 to re-perform the aforementioned steps, such that the iterative decoding steps are continuously performed.

The Normalized-BP algorithm considerably reduces complexity as compared to the LLR-BP algorithm. However, the Normalized-BP algorithm encounters greater BER performance deterioration as compared to the LLR-BP algorithm. FIG. 3 is a simulation result graph for the comparison between performances according to methods for decoding an LDPC code having a block length of 20000. Referring to FIG. 3, the BER of the Normalized-BP algorithm is less than that of the LLR-BP algorithm by about 0.07 dB. More specifically, the Normalized-BP algorithm has a disadvantage in that it unavoidably encounters performance deterioration.

### SUMMARY OF THE INVENTION

Therefore, the present invention has been designed in view of the above and other problems, and it is an object of the present invention to provide an apparatus and method for improving decoding performance of the Normalized-BP algorithm in an LDPC-code decoder.

It is another object of the present invention to provide a decoding apparatus for use in an LDPC-code decoding apparatus, which can be implemented in the form of a simpler configuration than the LLR-BP algorithm, and a method for controlling the same.

It is yet another object of the present invention to provide a decoding apparatus for use in an LDPC-code decoding apparatus, which improves decoding performance of the Normalized-BP algorithm and at the same time provides similar performance to that of the LLR-BP algorithm, and a method for controlling the same.

In accordance with one aspect of the present invention, the above and other objects can be accomplished by a Low Density Parity Check (LDPC)-code decoding apparatus for decoding symbols coded with LDPC-codes, comprising: a syndrome calculator for receiving parity values of the coded symbols, calculating a syndrome value using the received parity values, and generating the calculated syndrome value as a parity value; a comparison/selection unit for receiving channel reliability values of the coded symbols, receiving the syndrome value, selecting a reliability value having a lowest LLR (Log-Likelihood Ratio) from among the channel reliability values, and generating the selected reliability value; a switch for switching an output signal of the comparison/selection unit to one of three output terminals according to one of first to third switching control signals, respectively; first through third multipliers in which the three output terminals of the switch are connected to a first standardization factor α₁, a second standardization factor α₂, and a third standardization factor α₃, respectively, such that they output their reliability values; and a controller for receiving the output value from the comparison/selection unit, and generating the one of the first to third switching control signals according to a predetermined condition.

Preferably, the predetermined condition comprises: a first condition in which the first switching control signal connects the output value of the comparison/selection unit to the second multiplier when a resultant value of LLR-associated reliabilities having been modulo-operated using a specific value ‘2’ is equal to ‘0’; a second condition in which the second switching control signal connects the output value of the comparison/selection unit to the third multiplier when the modulo-operation result is equal to ‘1’, an input symbol value is a minimum value, and a bit node input value of the LDPC code is equal to the minimum value, and a third condition in which the third switching control signal connects the output value of the comparison/selection unit to the first multiplier when the modulo-operation result is equal to ‘1’, the input symbol value is not equal to a minimum value, and the bit node input value of the LDPC code is not equal to the minimum value.

In accordance with another aspect of the present invention, there is provided a Low Density Parity Check (LDPC)-code decoding method for decoding symbols coded with LDPC-codes, comprising the steps of: a) receiving initial coded symbols; b) performing initialization using individual values of received symbols; c) modulo-operating a sum of individual messages applied to bit nodes of the LDPC codes using a specific value of 2, and determining values of individual bit nodes; d) determining whether the determined values of the bit nodes are each equal to a specific value of 0; e) performing a row-directional iterative decoding process using a second standardization factor α₂ when the value of 0 is determined at the step (d); f) determining whether a current bit node value is equal to a minimum value when the value of 1 is determined at the step (d); g) performing a row-directional iterative decoding process using a first standardization factor α₁ when the current bit node value is not equal to the minimum value; h) performing a row-directional iterative decoding process using a third standardization factor α₃ when the current bit node value is equal to the minimum value; i) upon receiving a first iterative decoding result of the step (e), a second iterative decoding result of the step (g), and a third iterative decoding result of the step (h), performing a column-directional iterative decoding process using remaining values other than a corresponding node value; and j) performing a temporary decoding process using the column-directional iterative decoding result of the step (i), such that a parity check operation is performed.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a conceptual diagram illustrating a relationship between check nodes and variable nodes to explain a factor process for decoding the LDPC code;

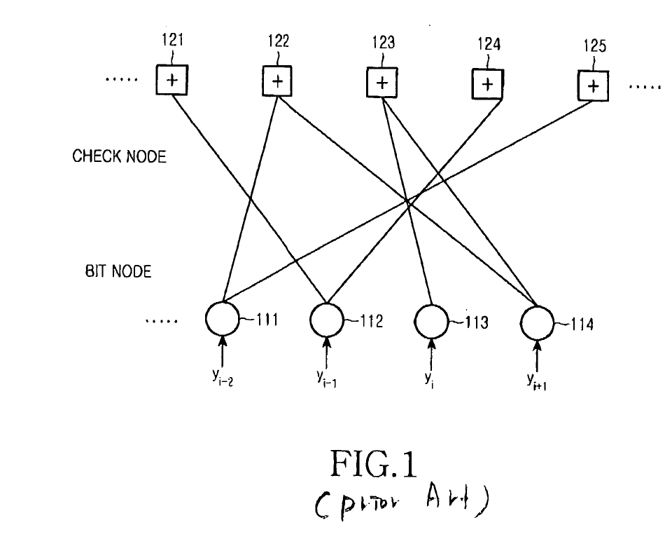

FIG. 2 is a flow chart illustrating the Normalized-BP algorithm from among a plurality of LDPC-code decoding methods;

FIG. 3 is a simulation result graph for a comparison between performances according to methods for decoding an LDPC code having a block length of 20000;

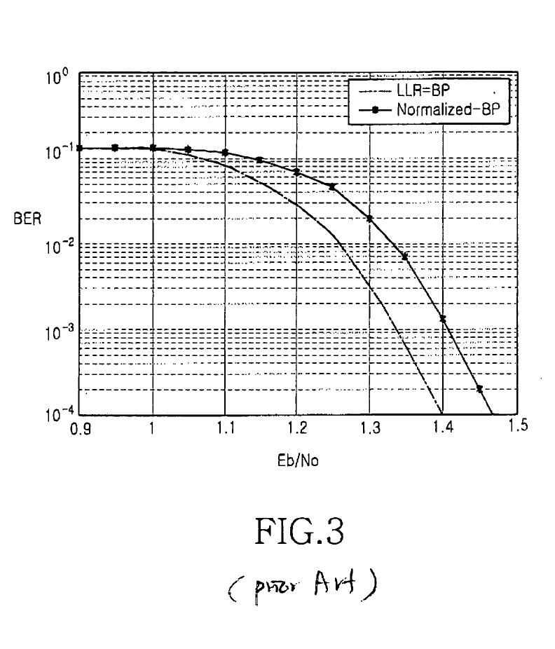

FIG. 4 is a flow chart illustrating a control method for use in an LDPC-code decoder in accordance with a preferred embodiment of the present invention;

FIG. 5 is a block diagram illustrating the LDPC-code decoder in accordance with a preferred embodiment of the present invention; and

FIG. 6 is a graph illustrating an SNR simulation result among the inventive algorithm, the LLR-BP algorithm, and the Normalized-BP algorithm when decoding an LDPC code having a block length of 20000 in accordance with a preferred embodiment of the present invention.

### DETAILED DESCRIPTION OF THE PREFERRED EMBODIMENTS

Preferred embodiments of the present invention will be described in detail herein below with reference to the annexed drawings. In the drawings, the same or similar elements are denoted by the same reference numerals even though they are depicted in different drawings. In the following description, a detailed description of known functions and configurations incorporated herein will be omitted when it may make the subject matter of the present invention rather unclear.

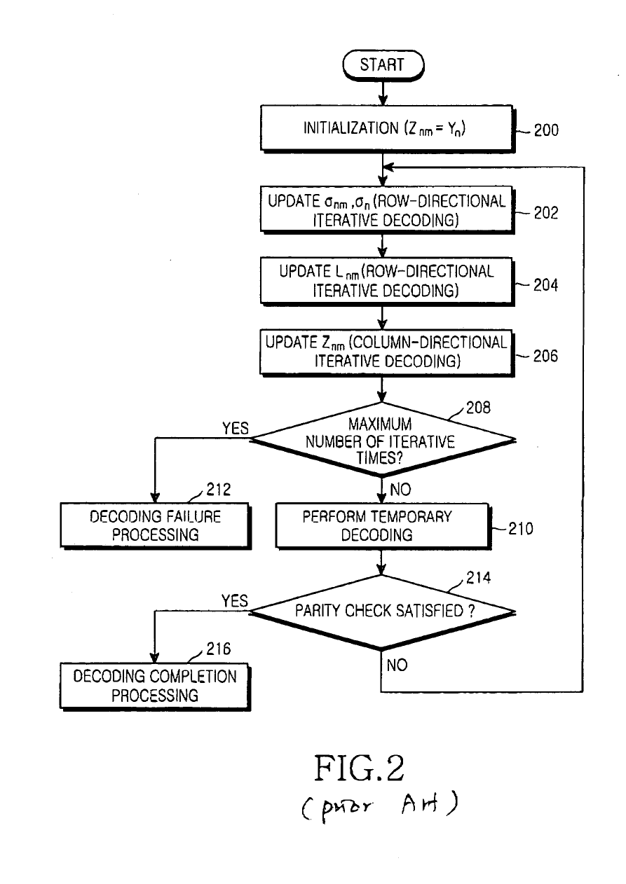

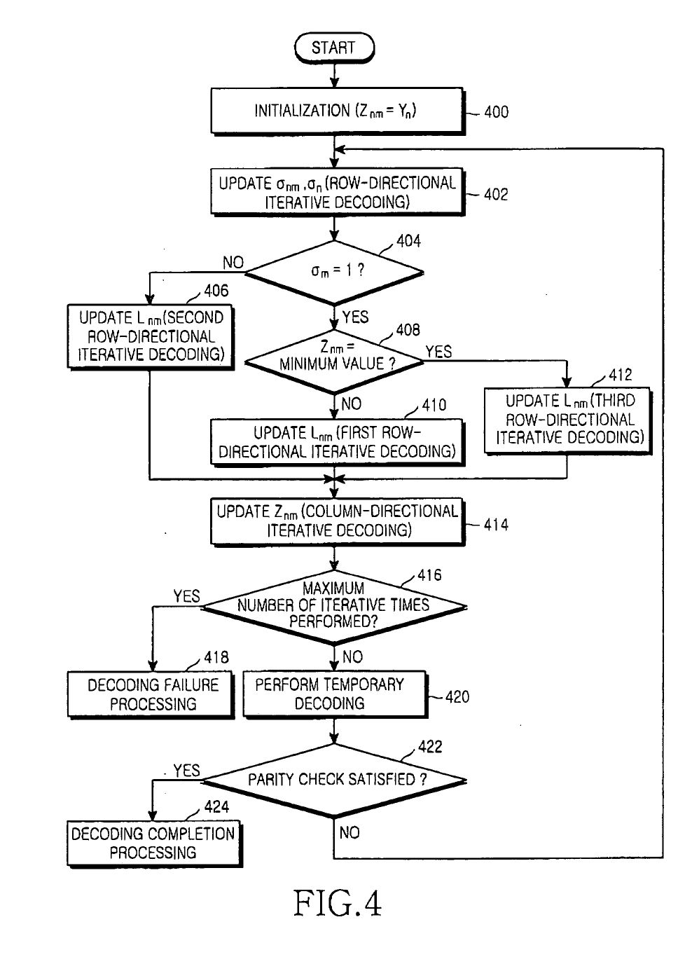

FIG. 4 is a flow chart illustrating a control method for use in an LDPC-code decoder in accordance with a preferred embodiment of the present invention. Referring to FIG. 4, the LDPC decoder performs an initialization process at step 400. This initialization process is the same as that of the conventional art illustrated in FIG. 2. After performing the initialization process at step 400, the LDPC decoder performs a row-directional iterative decoding process for updating values σₘₙ and σₙ at step 402 in the same manner as described in conjunction with FIG. 2. More specifically, the LDPC decoder calculates the sum of coded symbols received in a specific check node from among individual bit nodes using the mod-2 scheme as shown in Equation 1. According to the check result of a value Zₘₙ using the aforementioned calculation, there arise a first case of σₘₙ=0 and a second case of σₘₙ=1. The first case of σₘₙ=0 indicates the absence of errors, and the second case of σₘₙ=1 indicates the presence of errors.

After calculating the values of σₙ and σₘₙ at step 402, the LDPC decoder determines whether the value of σₘ is equal to ‘1’ at step 404. Step 404 determines whether the value of σₘ is equal to ‘1’ is determined by LDPC-code characteristics. The value of σₘ calculated at a specific time while performing either all reception coded symbols or an iterative decoding process has always been designed to be the value of 1 when there are errors. However, the value of σₘ comprises the sum of several values, instead of only one value, such that there are two cases in which the value of σₘ has the value of 1. More specifically, the first case occurs when the probability of generating such errors is in a low level. The second case occurs when the probability of generating such errors is in a high level.

Accordingly, if the check result of the above step 404 corresponds to the aforementioned two cases, i.e., if the value of σₘ has the value of 1, the LDPC decoder proceeds to step 408. However, if the check result of the step 404 does not correspond to the two cases, the LDPC decoder proceeds to step 406. If the LDPC decoder proceeds to step 406, this means there are no errors, such that it performs a second iterative decoding process in a row direction according to the present invention. In this case, the second iterative decoding process can be denoted by Equation 6.

$${( - 1 )}^{\overline{{σ}_{m} ⊕ {σ}_{mn}}} {min}_{{n}^{′} ∈ N ( m ) \backslash n} \vert {z}_{{mn}^{′}} \vert / {α}_{2} \qquad [ Equation 6 ]$$

Equation 6 has a value of a different from that of Equation 2 described in the conventional art. The present invention more precisely divides the tan h-curve standardization step for reducing the number of LLR-value calculations on the basis of the aforementioned reference. Therefore, the present invention more precisely divides not only a standardization factor used when only one or more odd errors occur, but also other factors, such that it can determine an appropriate factor value. The first case in which there is an error in factor values, and the remaining cases having no error in such factor values will be described in more detail herein below.

The LDPC decoder performs a row-directional iterative decoding process using a second standardization factor α₂ shown in Equation 6 at step 406.

If the value of σₘ is equal to ‘1’, the LDPC decoder determines whether the value of Zₘₙ is a minimum value at step 408. If it is determined that the value of Zₘₙ is the minimum value at step 408, the LDPC decoder proceeds to step 412. However, if the value of Zₘₙ is not equal to the minimum value at step 408, the LDPC decoder proceeds to step 410.

Because the value of Zₘₙ is an LLR value, it has high error generation probability on the condition that the value of Zₘₙ is equal to the minimum value. Therefore, if the value of Zₘₙ is equal to the minimum value, the LDPC decoder proceeds to step 412, such that it performs a row-directional iterative decoding process using a third standardization factor according to the present invention at step 412. A method for performing the row-directional iterative decoding using the third standardization factor can be represented by the following equation 7:

$${( - 1 )}^{\overline{{σ}_{m} ⊕ {σ}_{mn}}} {min}_{{n}^{′} ∈ N ( m ) \backslash n} \vert {z}_{{mn}^{′}} \vert / {α}_{3} \qquad [ Equation 7 ]$$

Equation 7 has a value of a different from that of Equation 2 described in the conventional art. If the value of Zₘₙ is not equal to the minimum value, i.e., if error generation probability is low, the LDPC decoder proceeds to step 410, such that it performs the row-directional iterative decoding process using the first standardization factor α₁, as shown in Equation 8:

$${( - 1 )}^{\overline{{σ}_{m} ⊕ {σ}_{mn}}} {min}_{{n}^{′} ∈ N ( m ) \backslash n} \vert {z}_{{mn}^{′}} \vert / {α}_{1} \qquad [ Equation 8 ]$$

Individual standardization factors can be represented by Equation 9:

α₁>α₂>α₃ [Equation 9]

The second standardization factor α₂ from among individual standardization factors of the present invention may be equal to the standardization factor α described in the conventional art, and may have other values different from the standardization factor α. Individual standardization factors of the present invention must always maintain the relationship denoted by Equation 9, regardless of the second standardization factor α₂.

The LDPC decoder proceeds to step 414 after the row-directional iterative decoding process has been completed at step 406, 410, or 412. The LDPC decoder performs a column-directional iterative decoding process for updating the value of Zₘₙ equal to the aforementioned LLR. The column-directional iterative decoding process performs an iterative decoding process using Equation 3 in the same manner as in the conventional art.

Upon completing the column-directional iterative decoding process, the LDPC decoder proceeds to step 416, such that it determines whether the number of current iterative times reaches a maximum number of iterative times at step 416. If it is determined that the number of current iterative times is equal to the maximum number of iterative times at step 416, the LDPC decoder informs corresponding reception coded symbols of a decoding failure at step 418 in such a way that it performs a corresponding process accompanied with the decoding failure.

However, if the number of current iterative times does not reach the maximum number of iterative times at step 416, the LDPC decoder proceeds to step 420, such that it performs a temporary decoding process as shown in Equation 4. The LDPC decoder proceeds to step 422, such that it performs a parity check process using the temporary decoded result. If the parity check process has been satisfied according to the parity check result, the LDPC decoder finishes decoding currently-received coded symbols at step 424. However, if the parity check process has not been satisfied according to the parity check result, the LDPC decoder returns to step 402, such that it repeats the above described steps 402 to 422. As a result, the LDPC decoder can more correctly decode the LDPC.

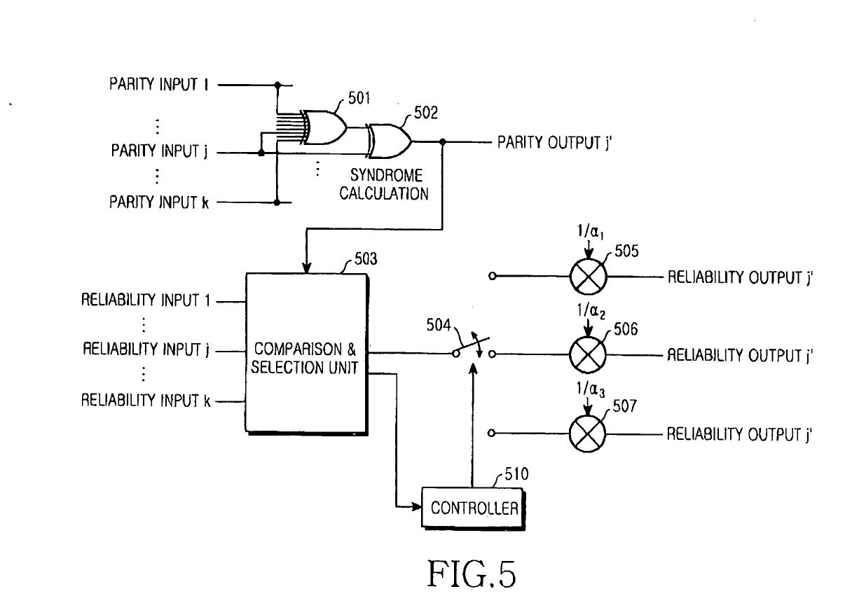

FIG. 5 is a block diagram illustrating the LDPC-code decoder in accordance with a preferred embodiment of the present invention. Referring to FIG. 5, two operators 501 and 502 for calculating syndrome values, upon receiving parity input values, are syndrome calculators that can also be used for the Normalized-BP algorithm described in the conventional art, such that their detailed descriptions will herein be omitted for the convenience of description. However, it should be noted that the present invention enters the syndrome value in a Comparison & Selection unit 503, whereas the conventional art uses the syndrome value calculated by the Normalized-BP algorithm as a parity output value only. The Comparison & Selection unit 503 receives reliability values of individual coded symbols as input values. The Comparison & Selection unit 503 selects one reliability value from among the reliability values using the parity output value, and outputs the selected reliability value. The output reliability value of the Comparison & Selection unit 503 is determined to be reliability of a bit having a lowest LLR from among a plurality of bits associated with the parity check equation, such that the Comparison & Selection unit 503 outputs the determined reliability value.

The selected value is transmitted to a controller 510 and a switch 504. The controller 510 outputs a switching control signal using the output value of the Comparison & Selection unit 503. The controller 510 uses the output value of the Comparison & Selection unit 503 as reliability values, such that it may directly receive/process such reliability values if needed. The controller 510 determines whether the value of σₘ illustrated in FIG. 4 is equal to ‘1’. If it is determined that the value of σₘ is equal to ‘1’, the controller 510 calculates the received value to determine whether the value of Zₘₙ is equal to a minimum value. If it is determined that the value of Zₘₙ is not equal to the minimum value, the controller 510 outputs a switching control signal to connect the switch 504 to a second multiplier 506. If the value of Zₘₙ is equal to the minimum value, the controller 510 outputs a switching control signal to connect the switch 504 to a third multiplier 507. If the value of Zₘₙ is not equal to the minimum value, the controller 510 outputs a switching control signal. In the meantime, if it is determined that the value of σₘ is not equal to ‘1’, the controller 510 outputs a switching control signal to connect the switch 504 to a first multiplier 505.

As stated above, the number of output terminals of the switch 504 is 3, and individual multipliers 505, 506, and 507 are connected to individual output terminals. The first multiplier 505 adapts a predetermined value to be divided by the first standardization factor α₁ as another input value, the second multiplier 506 adapts a predetermined value to be divided by the second standardization factor α₂ as another input value, and the third multiplier 507 adapts a predetermined value to be divided by the third standardization factor α₂ as another input value. Therefore, the value passing through the switch 504 after having been generated from the Comparison & Selection unit 503 is divided by a corresponding factor, such that it is generated in the form of changed reliability values of the present invention. It should be noted that a temporary decoding and its associated parity check devices are not shown in the annexed drawings because the temporary decoding and its associated parity check devices can also be implemented in the form of the same configuration as in the conventional art.

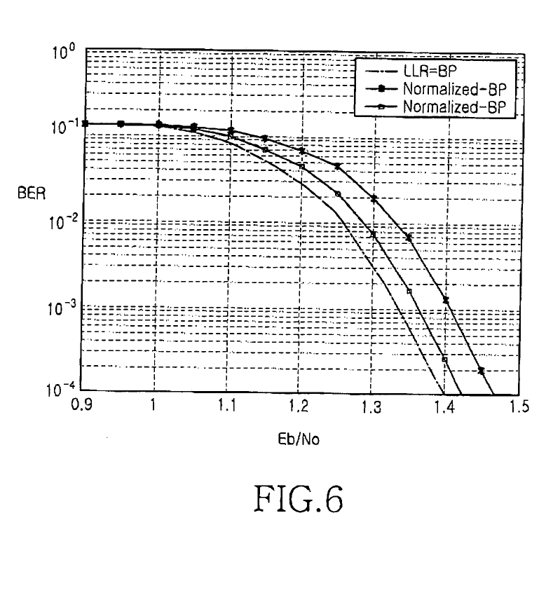

FIG. 6 is a graph illustrating an SNR simulation result among the inventive algorithm, the LLR-BP algorithm, and the Normalized-BP algorithm in the case of decoding an LDPC code having a block length of 20000 in accordance with a preferred embodiment of the present invention. The inventive graph is denoted by “Modified Normalized-BP” in FIG. 6. As can be seen from FIG. 6, the inventive method of the present invention can improve decoding-process performance much more than the conventional Normalized-BP algorithm. The algorithm compared with the Normalized-BP algorithm does not require additional multiplication operation, except for a process selecting an appropriate standardization factor value, such that it also has advantages of the conventional Normalized-BP algorithm in association with complexity. As can be seen from the simulation result of FIG. 6, the inventive method approximates about 0.02 dB of the LLR-BP algorithm at the same complexity as in the Normalized-BP algorithm.

As is apparent from the above description, the present invention is adapted to the LDPC-code decoding process for use in a communication system, such that it can prevent performance deterioration and can also perform such a decoding operation using only a simple circuit configuration.

Although the preferred embodiments of the present invention have been disclosed for illustrative purposes, those skilled in the art will appreciate that various modifications, additions and substitutions are possible, without departing from the scope and spirit of the present invention as disclosed in the accompanying claims.

What is claimed is:

1. A Low Density Parity Check (LDPC)-code decoding apparatus for decoding symbols coded with LDPC-codes, comprising:
a syndrome calculator for receiving parity values of the coded symbols, calculating a syndrome value using the received parity values, and generating the calculated syndrome value as a parity value;
a comparison/selection unit for receiving channel reliability values of the coded symbols, receiving the syndrome value, selecting a reliability value having a lowest LLR (Log-Likelihood Ratio) from among the channel reliability values, and generating the selected reliability value;
a switch for switching an output signal of the comparison/selection unit to one of three output terminals according to one of first to third switching control signals, respectively;
first through third multipliers in which the three output terminals of the switch are connected to a first standardization factor α₁, a second standardization factor α₂, and a third standardization factor α₃, respectively, such that they output their reliability values; and
a controller for receiving the output value from the comparison/selection unit, and generating the one of the first to third switching control signals according to a predetermined condition.

2. The apparatus according to claim 1, wherein the predetermined condition comprises:
a first condition in which the first switching control signal connects the output value of the comparison/selection unit to the second multiplier when a resultant value of LLR-associated reliabilities having been modulo-operated using a specific value ‘2’ is equal to ‘0’;
a second condition in which the second switching control signal connects the output value of the comparison/selection unit to the third multiplier when the modulo-operation result is equal to ‘1’, an input symbol value is a minimum value, and a bit node input value of the LDPC code is equal to the minimum value, and
a third condition in which the third switching control signal connects the output value of the comparison/selection unit to the first multiplier when the modulo-operation result is equal to ‘1’, the input symbol value is not equal to a minimum value, and the bit node input value of the LDPC code is not equal to the minimum value.

3. The apparatus according to claim 1, wherein the first standardization factor α₁ is higher than the second standardization factor α₂, which is higher than the third standardization factor α₃.

4. The apparatus according to claim 1, further comprising:
a temporary decoder for performing a temporary decoding process using the parity output value and the reliability output values, and terminating the decoding process of symbols.

5. The apparatus according to claim 1, further comprising:
a temporary decoder for performing a temporary decoding process using the parity output value and the reliability output values, and performing an iterative decoding process according to the temporary decoding result

6. The apparatus according to claim 5, wherein the temporary decoder includes:
a counter for determining whether a number of the iterative decoding times reaches a predetermined number of decoding times, increasing its counter value for every decoding operation, and further performing a decoding failure process when the decoding process is not completed until decoded values reach values predetermined by the counter value.

7. A Low Density Parity Check (LDPC)-code decoding method for decoding symbols coded with LDPC-codes, comprising the steps of:
a) receiving initial coded symbols,
b) performing initialization using individual values of received symbols;
c) modulo-operating a sum of individual messages applied to bit nodes of the LDPC codes using a specific value of 2, and determining values of individual bit nodes;
d) determining whether the determined values of the bit nodes are each equal to a specific value of 0;
e) performing a row-directional iterative decoding process using a second standardization factor α₂ when the value of 0 is determined at the step (d);
f) determining whether a current bit node value is equal to a minimum value when the value of 1 is determined at the step (d);
g) performing a row-directional iterative decoding process using a first standardization factor α₁ when the current bit node value is not equal to the minimum value;
h) performing a row-directional iterative decoding process using a third standardization factor α₃ when the current bit node value is equal to the minimum value;
i) upon receiving a first iterative decoding result of the step (e), a second iterative decoding result of the step (g), and a third iterative decoding result of the step (h), performing a column-directional iterative decoding process using remaining values other than a corresponding node value; and
j) performing a temporary decoding process using the column-directional iterative decoding result of the step (i), such that a parity check operation is performed.

8. The method according to claim 7, wherein the first standardization factor α₁ is higher than the second standardization factor α₂, which is higher than the third standardization factor α₃.

9. The method according to claim 7, wherein the row-directional iterative decoding process of step (e) is calculated by:
$${( - 1 )}^{\overline{{σ}_{m} ⊕ {σ}_{mn}}} {min}_{{n}^{′} ∈ N ( m ) \backslash n} \vert {z}_{{mn}^{′}} \vert / {α}_{2}$$
where σₘₙ is represents values received from a bit node ‘m’ to an n-th check node, σₘ is a value determined by an m-th bit node, Zₘₙ is an LLR of the bit ‘n’ propagated from the bit ‘n’ to a parity check equation ‘m’, and α₂ is the second standardization factor.

10. The method according to claim 7, wherein the row-directional iterative decoding process of step (g) is calculated by:
$${( - 1 )}^{\overline{{σ}_{m} ⊕ {σ}_{mn}}} {min}_{{n}^{′} ∈ N ( m ) \backslash n} \vert {z}_{{mn}^{′}} \vert / {α}_{3}$$
where σₘₙ is represents values received from a bit node ‘m’ to an n-th check node, σₘ is a value determined by an m-th bit node, Zₘₙ is an LLR of the bit ‘n’ propagated from the bit ‘n’ to a parity check equation ‘m’, and α₃ is the third standardization factor.

11. The method according to claim 7, wherein the row-directional iterative decoding process of step (h) is calculated by:
$${( - 1 )}^{\overline{{σ}_{m} ⊕ {σ}_{mn}}} {min}_{{n}^{′} ∈ N ( m ) \backslash n} \vert {z}_{{mn}^{′}} \vert / {α}_{1}$$
where σₘₙ is represents values received from a bit node ‘m’ to an n-th check node, σₘ is a value determined by an m-th bit node, Zₘₙ is an LLR of the bit ‘n’ propagated from the bit ‘n’ to a parity check equation ‘m’, and α₁ is the first standardization factor.

12. The method according to claim 7, further comprising the step of:
k) if the parity check result indicates a parity error occurrence, repeating the steps (c) to (j) a predetermined number of times.
